(19) United States
(12) Patent Application Publication
(10) Pub. No.: US 2024/0114737 A1
(43) Pub. Date: Apr. 4, 2024

(54) DISPLAY PANEL AND DISPLAY DEVICE

(71) Applicant: WUHAN TIANMA MICRO-ELECTRONICS CO., LTD., Wuhan (CN)

(72) Inventors: Qin YUE, Wuhan (CN); Yangzhao MA, Wuhan (CN)

(73) Assignee: WUHAN TIANMA MICRO-ELECTRONICS CO., LTD., Wuhan (CN)

(21) Appl. No.: 18/540,037

(22) Filed: Dec. 14, 2023

(30) Foreign Application Priority Data
Dec. 27, 2022 (CN) 202211687162.8

(51) Int. Cl. H10K 59/131

(52) U.S. Cl. CPC H10K 59/131

(57) ABSTRACT

A display panel includes data lines and a first wiring layer in a display region, and a cover layer located at a side of the first wiring layer facing toward a light-exiting direction of the display panel. The first wiring layer includes data connection lines and wiring segments. The data connection line is connected to a data lines and transmits a data voltage provided in the pad region to the data line. One wiring segment is spaced apart from the data connection line by a first breaking. The cover layer includes first cover portions and second cover portions. Along a direction perpendicular to a plane of the display panel, the first cover portions overlap the first breakings, and the second cover portions overlap the data connection lines and the wiring segments. The first cover portion has a thickness smaller than a thickness of the second cover portion.

### CROSS-REFERENCE TO RELATED APPLICATIONS

The present application claims priority to Chinese Patent Application No. 202211687162.8, filed on Dec. 27, 2022, the content of which is incorporated herein by reference in its entirety.

### TECHNICAL FIELD

The present disclosure relates to the technical field of display, and in particular, to a display panel and a display device.

### BACKGROUND

In recent years, with the continuous development of display technology, a screen-to-body ratio of a display panel has become larger and larger, bringing users a better visual experience.

In order to further reduce a width of a lower bezel, some of fan-out lines are arranged in a display region, which is known as the fan-out in AA (FIAA) technology. The FIAA technology needs to arrange connection lines in the display region. However, defects, such as always-on display mura, may be caused due to arranging the connection lines in the display region.

### SUMMARY

In a first aspect, a display panel is provided. The display panel has a display region and a pad region, and includes a plurality of data lines arranged in the display region, a first wiring layer in the display region, and a cover layer located at a side of the first wiring layer facing toward a light-exiting direction of the display panel. The first wiring layer includes a plurality of data connection lines and a plurality of wiring segments. One data connection line of the plurality of data connection lines is connected to at least one data line of the plurality of data lines and is configured to transmit a data voltage provided in the pad region to the at least one data line. One wiring segment of the plurality of wiring segments is spaced apart from one data connection line of the plurality of data connection lines by one first breaking of first breakings. The cover layer includes first cover portions and second cover portions. Along a direction perpendicular to a plane of the display panel, the first cover portions overlap the first breakings, respectively, and the second portions overlap the plurality of data connection lines and the plurality of wiring segments. One of the first cover portions has a thickness smaller than a thickness of one of the second cover portions.

In a second aspect, a display device is provided. The display panel has a display region and a pad region, and includes a plurality of data lines arranged in the display region, a first wiring layer in the display region, and a cover layer located at a side of the first wiring layer facing toward a light-exiting direction of the display panel. The first wiring layer includes a plurality of data connection lines and a plurality of wiring segments. One data connection line of the plurality of data connection lines is connected to at least one data line of the plurality of data lines and is configured to transmit a data voltage provided in the pad region to the at least one data line. One wiring segment of the plurality of wiring segments is spaced apart from one data connection line of the plurality of data connection lines by one first breaking of first breakings. The cover layer includes first cover portions and second cover portions. Along a direction perpendicular to a plane of the display panel, the first cover portions overlap the first breakings, respectively, and the second portions overlap the plurality of data connection lines and the plurality of wiring segments. One of the first cover portions has a thickness smaller than a thickness of one of the second cover portions.

### BRIEF DESCRIPTION OF DRAWINGS

In order to more clearly illustrate the technical solutions in the embodiments of the present disclosure, the accompanying drawings used in the description of the embodiments will be briefly introduced below. The accompanying drawings in the following description are only some embodiments of the present disclosure, and other drawings can be obtained by those of ordinary skill in the art from the drawings.

FIG. 1 is a schematic structural diagram of a display panel provided in the related art.

FIG. 2 is a schematic structural diagram of another display panel provided in the related art.

FIG. 3 is a schematic structural diagram of a display panel according to embodiments of the present disclosure.

FIG. 4 is an enlarged view of a region of FIG. 3.

FIG. 5 is a schematic diagram showing layers of a display panel according to embodiments of the present disclosure.

FIG. 6 is a cross-sectional view along line A1-A2 in FIG. 5.

FIG. 7 is another schematic structural diagram of a display panel according to embodiments of the present disclosure.

FIG. 8 is an enlarged view of a region of FIG. 7.

FIG. 9 is a schematic diagram showing layers of a display panel according to embodiments of the present disclosure.

FIG. 10 is a cross-sectional view along line B1-B2 in FIG. 9.

FIG. 11 is a cross-sectional view along line C1-C2 in FIG. 9.

FIG. 12 is a schematic diagram showing a thickness of a cover layer according to embodiments of the present disclosure.

FIG. 13 is a schematic diagram showing a layout of first portions and first breakings according to embodiments of the present disclosure.

FIG. 14 is a schematic diagram showing a thickness of a cover layer according to embodiments of the present disclosure.

FIG. 15 is another schematic structural diagram of a display panel according to embodiments of the present disclosure.

FIG. 16 is an enlarged view of a partial region of FIG. 15.

FIG. 17 is a schematic diagram showing layers of a display panel according to embodiments of the present disclosure.

FIG. 18 is a cross-sectional view along line D1-D2 in FIG. 17.

FIG. 19 is a schematic diagram showing a thickness of a cover layer according to embodiments of the present disclosure.

FIG. 20 is a schematic diagram showing a layout of first breakings and second breakings according to embodiments of the present disclosure.

FIG. 21 is a schematic diagram showing a partial structure of a display panel according to embodiments of the present disclosure.

FIG. 22 is a cross-sectional view along line E1-E2 in FIG. 21.

FIG. 23 is another schematic structural diagram of a display panel according to embodiments of the present disclosure.

FIG. 24 is a cross-sectional view along line F1-F2 in FIG. 23.

FIG. 25 is a schematic diagram showing a layout of third portions and first breakings according to embodiments of the present disclosure.

FIG. 26 is a schematic structural diagram showing another partial region of a display panel according to embodiments of the present disclosure.

FIG. 27 is a cross-sectional view along line G1-G2 in FIG. 26.

FIG. 28 is a cross-sectional view showing layers of a display panel according to embodiments of the present disclosure.

FIG. 29 is another cross-sectional view showing layers of a display panel according to embodiments of the present disclosure.

FIG. 30 is another cross-sectional view showing layers of a display panel according to embodiments of the present disclosure.

FIG. 31 is a schematic structural diagram showing another partial region of a display panel according to embodiments of the present disclosure.

FIG. 32 is a cross-sectional view along line H1-H2 in FIG. 31.

FIG. 33 is a schematic structural diagram showing another partial region of a display panel according to embodiments of the present disclosure.

FIG. 34 is a cross-sectional view along line I1-I2 in FIG. 33.

FIG. 35 is a schematic structural diagram showing another partial region of a display panel according to embodiments of the present disclosure.

FIG. 36 is a cross-sectional view along line J1-J2 in FIG. 35.

FIG. 37 is a schematic structural diagram of a first breaking according to embodiments of the present disclosure.

FIG. 38 is another schematic structural diagram of a display panel according to embodiments of the present disclosure.

FIG. 39 is an enlarged view of a partial region of FIG. 38.

FIG. 40 is another schematic diagram showing layers of a display panel according to embodiments of the present disclosure.

FIG. 41 is a cross-sectional view along line L1-L2 in FIG. 40.

FIG. 42 is a cross-sectional view along line M1-M2 in FIG. 40.

FIG. 43 is a schematic diagram showing a layout of fifth cover portions and first breakings according to embodiments of the present disclosure.

FIG. 44 is a schematic diagram of a pixel circuit according to embodiments of the present disclosure.

FIG. 45 is a schematic structural diagram of a display device according to embodiments of the present disclosure.

### DESCRIPTION OF EMBODIMENTS

For facilitating the understanding of the technical solution of the present disclosure, the embodiments of the present disclosure are described in detail as below.

It should be understood that the embodiments described below are merely some of, rather than all of the embodiments of the present disclosure. On a basis of the embodiments in this disclosure, all other embodiments obtained by the ordinary skilled in the art fall within a scope of this disclosure.

The terms used in the embodiments of the present disclosure are merely for the purpose of describing specific embodiments, but not intended to limit the present disclosure. The singular forms of “a”, “an” and “the” used in the embodiments of the present disclosure and the appended claims are also intended to indicate plural forms, unless clearly indicating others.

It should be understood that the term “and/or” used herein merely indicates a relationship describing associated objects, indicating three possible relationships. For example, the expression “A and/or B” indicates: A alone, both A and B, or B alone. The character “/” in this description generally means that the associated objects are in an “or” relationship.

In order to display images normally, the display panel is provided with data lines in the display region. These data lines are connected to pads though fan-out lines extending in the lower bezel region, achieving the electrical connection between the data lines and the pins. However, arranging the fan-out lines in the lower bezel region causes a large bezel r width of the display panel, and is not conducive to optimizing the sizes of the lower bezel region.

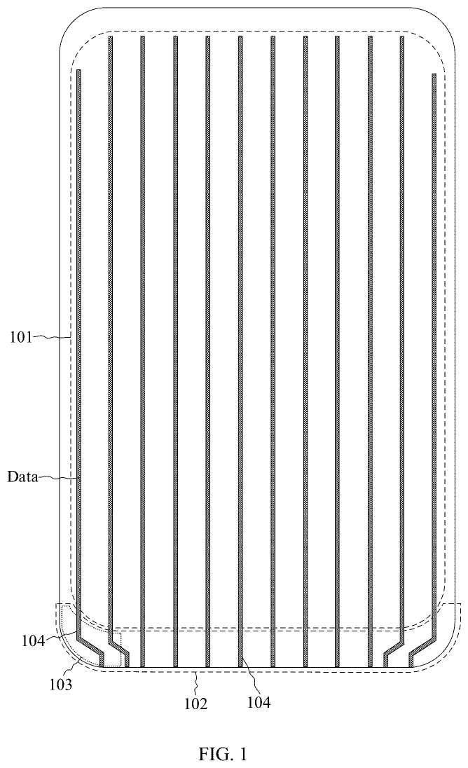

A display panel with a rounded rectangle shape is taken as an example. FIG. 1 is a schematic structural diagram of a display panel provided in the related art. As shown in FIG. 1, a display panel includes a display region 101 and a lower bezel 102. The lower bezel 102 includes a corner region 103. The corner region 103 is located at a corner of the display panel, and is also referred to as an R-corner region. An edge of the corner region 103 may be an arc.

Multiple data lines Data are arranged in the display region 101, and an end of the data line Data close to a bottom of the display region 101 is connected to a fan-out line 104 in the lower bezel 102, and then is connected to a pad through the fan-out line 104. The data lines Data include some data lines Data adjacent to the edge of the display region 101, and the fan-out lines 104 connected to the data lines Data are bent in the corner region 103 and then extend to the pads. The fan-out lines 104 occupy a large width in the corner region 103, causing a large overall width of the lower frame 102.

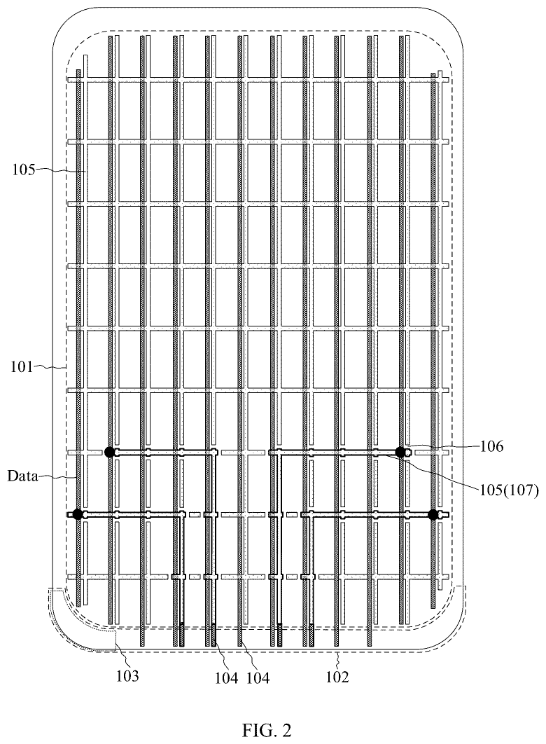

In view of the above problem, another display panel is provided. FIG. 2 is a schematic structural diagram of another display panel provided in the related art. As shown in FIG. 2, the display panel includes a wiring layer 105 in the display region 101. The wiring layer 105 includes a plurality of breakings 106, and a plurality of data connection lines 107 that are independent from each other. The data connection line 107 is connected to the data line Data adjacent to the edge of the display region 101, and an end of the data connection line 107 is extended to a middle position of the bottom of the display region 101. In this way, the fan-out line 104 corresponding to the data line Data is directly connected to the data connection line 107 at the middle position of the bottom of the display region 101 without extending in the corner region 103. Therefore, the width of the corner region 103 can be greatly reduced, and the narrow bezel design of the display panel can be improved.

There is no meal material of the wiring layer 105 at the breakings 106 of the wiring layer 105, the reflectivity of the breaking 106 to the external light and the reflectivity of the position where no breaking 106 is arranged are different, causing that the amounts of the external lights reflected by different positions are different and the display panel has an obvious mura phenomenon in the always-on display mode.

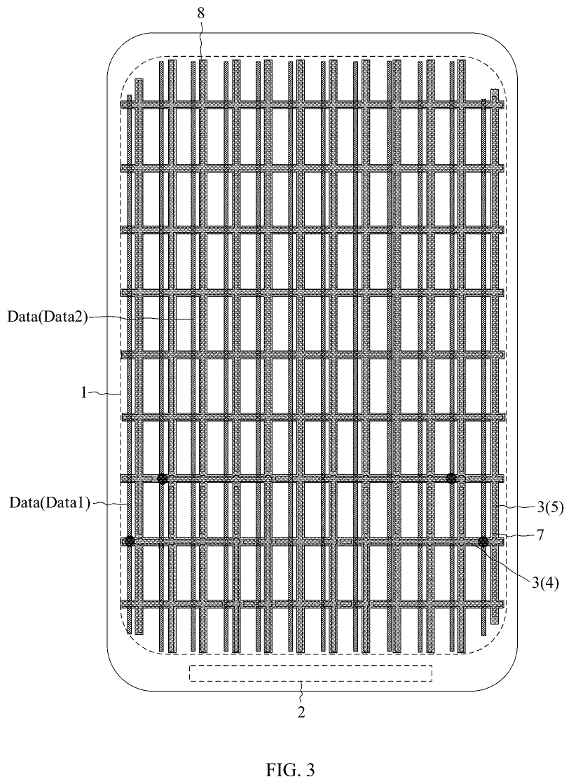

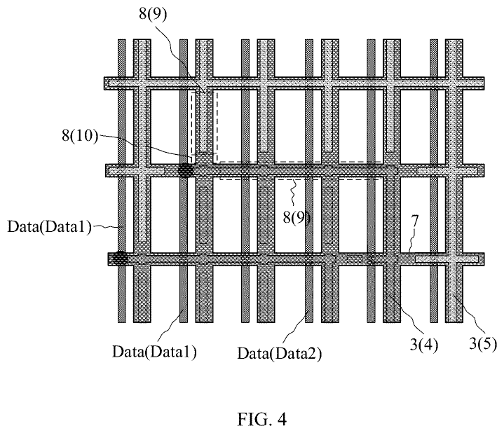

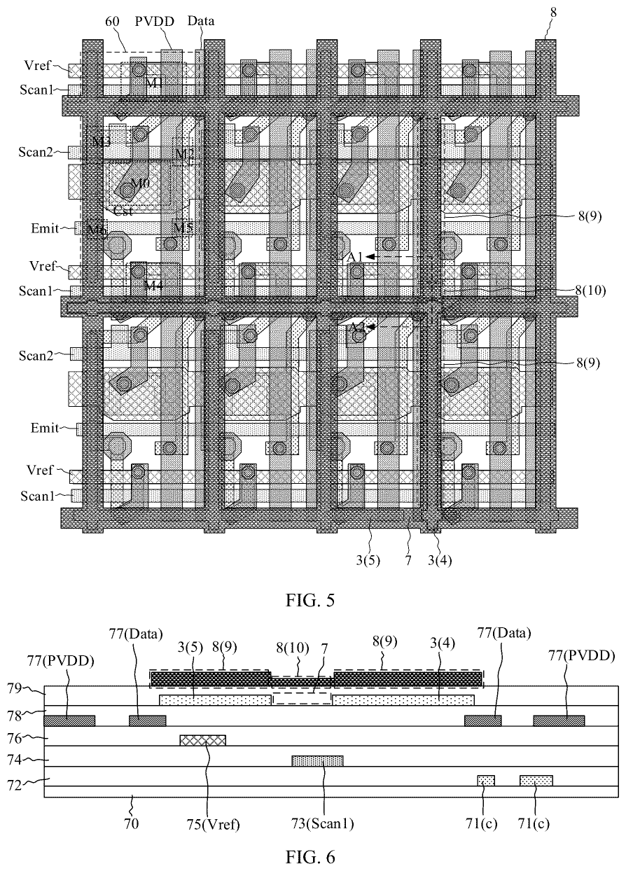

In view of the above, embodiments of the present disclosure provide a display panel. FIG. 3 is a schematic structural diagram of a display panel according to embodiments of the present disclosure. FIG. 4 is an enlarged view of a region of FIG. 3. FIG. 5 is a schematic diagram showing layers of a display panel according to embodiments of the present disclosure. FIG. 6 is a cross-sectional view along line A1-A2 in FIG. 5. As shown in FIG. 3 to FIG. 6, the display panel has a display region 1 and a pad region 2, and includes data lines Data located in the display region 1 and a first wiring layer 3 located in the display region 1.

The first wiring layer 3 includes data connection lines 4 and wiring segments 5. At least one wiring segment 5 each is spaced apart from at least one data connection line 4 by a first breaking 7. At least two data connection lines 4 are connected to at least two data lines Data, respectively, and each are configured to transmit a data voltage provided by the pads in the pad region 2 to the at least two data lines Data.

In some embodiments, as shown in FIG. 3, the data lines Data include edge data lines Data1 and middle data lines Data2. The edge data lines Data1 are arranged at two sides of the middle data line Data2, that is, the edge data lines Data1 are closer to the edge of the display region 1 than the middle data lines Data2. The data connection lines 4 are connected to the edge data lines Data1, respectively. The data connection lines 4 extend to a middle region of the display region 1. The fan-out lines corresponding to the edge data lines Data1 can directly extend from the middle region of the display region 1 to the pad region 2 and be connected to the pads, thereby reducing the width of the corner bezel.

The display panel includes a cover layer 8. The cover layer 8 is located at a side of the first wiring layer 3 close to the light-exiting side of the display panel. The cover layer 8 includes a plurality of first cover portions 10 and a plurality of second cover portions 9. In a direction perpendicular to a plane of the display panel, the first cover portion overlaps the first breaking 7, and the second cover portions 9 overlap the data connection line 4 and the wiring segment 5. A thickness of the second cover portion 9 is greater than a thickness of at least one first cover portion 10.

In embodiments of the present disclosure, the cover layer 8 is arranged above the first wiring layer 3, and different positions of the cover layer 8 have different thicknesses. The reflectivity difference at different positions due to the first breaking 7 is reduced by the thickness configuration of the cover layer 8. For example, the first cover portion 10 of the cover layer 8 overlapping the first breaking 7 has a thickness smaller than the thickness of the second cover portion 9. The absorbing degree or blocking degree of the first cover portion 10 to the ambient light is reduced, such that ambient light can pass through the first cover portion 10 and be incident on the first breaking 7, and then be reflected back by the sidewall of the wiring segment 5 and the sidewall of the data connection line 4. In this way, the reflectivity at the first breaking 7 is effectively increased, the reflectivity difference between the first breaking 7 of the first wiring layer 3 and the position of the first wiring layer 3 where no first breaking 7 is arranged is reduced, and the mura phenomenon in the always-on display mode due to the first breaking 7 is effectively weakened.

As shown in FIG. 5, the display panel further includes a plurality of pixel circuits 60, and each pixel circuit 60 includes a storage capacitor Cst and transistors. The transistors include a driving transistor M0, a gate reset transistor M1, a data input transistor M2, a threshold compensation transistor M3, an anode reset transistor M4, a first emission control transistor M5, and a second emission control transistor M6. The structure and operation principle of the pixel circuit 60 are described in details below.

In some embodiments, as shown in FIG. 6, the display panel includes a substrate 70, a semiconductor layer 71, a gate insulation layer 72, a first metal layer 73, a first interlayer dielectric layer 74, a second metal layer 75, a second interlayer dielectric layer 76, a third metal layer 77, and a fourth interlayer dielectric layer 78. The semiconductor layer 71, the gate insulation layer 72, the first metal layer 73, the first interlayer dielectric layer 74, the second metal layer 75, the second interlayer dielectric layer 76, the third metal layer 77, and the fourth interlayer dielectric layer 78 are sequentially arranged on the substrate 70. Active layers of the transistors and connection lines c between the transistors are formed in the semiconductor layer 71. Gates of the transistors, a first plate of the storage capacitor Cst, a first scan signal line Scan1, a second scan signal line Scan2, and an emission control signal line Emit are formed in the first metal layer 73. A second plate c2 of the storage capacitor Cst and a reset signal line Vref are formed in the second metal layer 75. First electrodes and second electrodes of the transistors, the data lines Data, and a power supply line PVDD are formed in the third metal layer 77.

As shown in FIG. 6, the first wiring layer 3 and the cover layer 8 are spaced apart from each other by at least one first insulation layer 79.

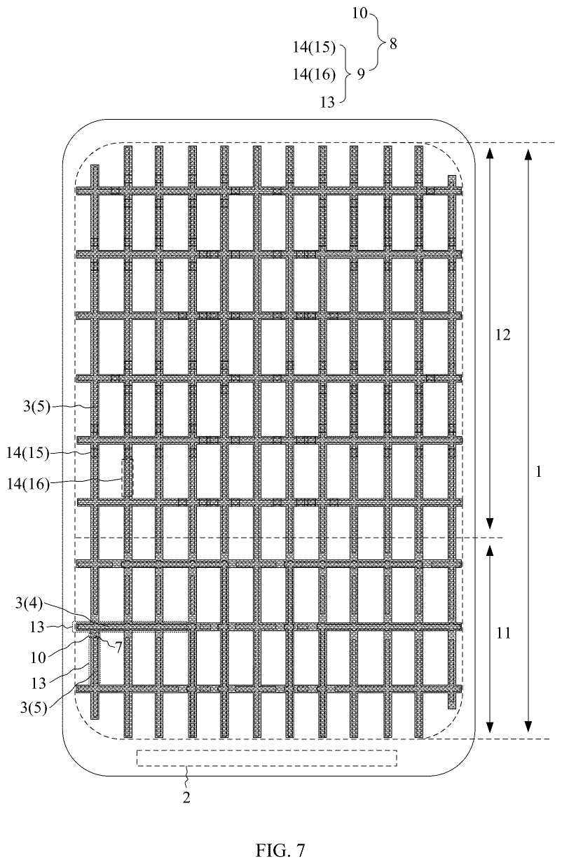

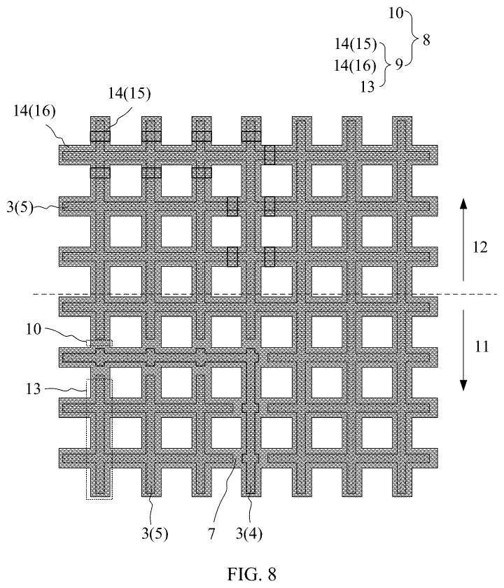

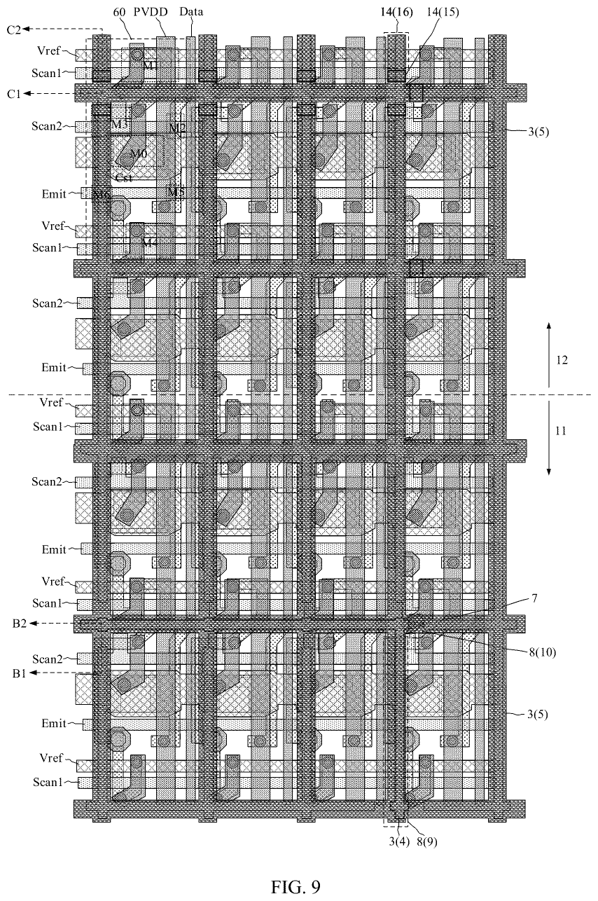

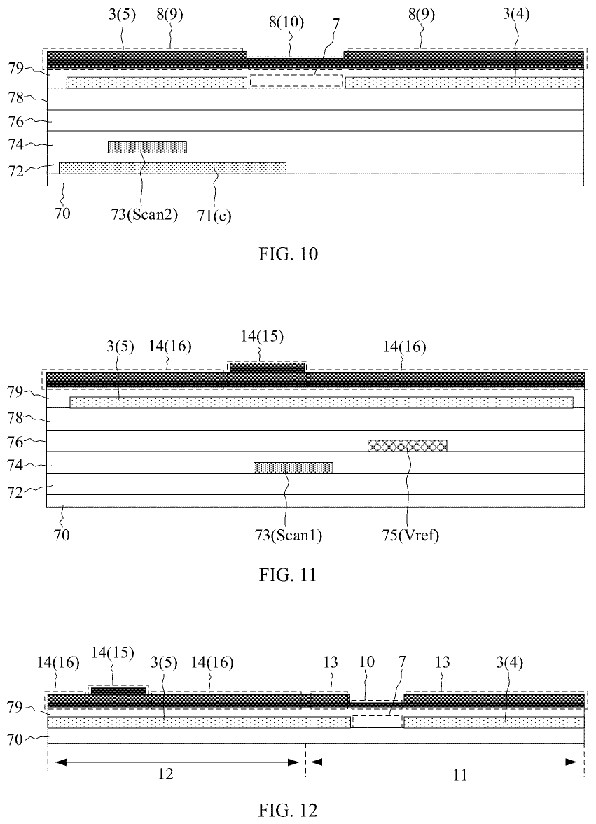

FIG. 7 is another schematic structural diagram of a display panel according to embodiments of the present disclosure. FIG. 8 is an enlarged view of a region of FIG. 7. FIG. 9 is a schematic diagram showing layers of a display panel according to embodiments of the present disclosure. FIG. 10 is a cross-sectional view along line B1-B2 in FIG. 9. In some embodiments, as shown in FIG. 7 to FIG. 10, the display region 1 includes a first display region 11 and a second display region 12. The first display region 11 is located at a side of the second display region 12 close to the pad region 2. The data connection lines 4 and the first breakings 7 are arranged in the first display region 11. One wiring segment 5 is arranged in the first display region 11, and another wiring segment 5 is arranged in the second display region 12.

The second cover portions 9 include a first portion 13 arranged in the first display region 11. In the direction perpendicular to the plane of the display panel, the first portions 13 overlap the data connection line 4 and the wiring segment 5 that are located in the first display region 11. The thickness of the first cover portion 10 is smaller than the thickness of the first portion 13.

In the above configuration, the data connection lines 4 are all arranged in the first display region 11 that is closer to the pad region 2 than the second display region 12, such that the extending length of the data connection line 4 can be reduced, reducing the difference between the attenuation of the data voltage transmitted by the edge data line Data1 and the attenuation of the data voltage transmitted by the middle data line Data2. With such configuration, the first breakings 7 are all arranged in the first display region 11. As a result, in the always-on display mode, the first breakings 7 may cause the mura phenomenon in the first display region 11. In view of this, the display panel of embodiments of the present disclosure is configured in the following manner. The first cover portion 10 and the first portion 13 of the cover layer 8 located in the first display region 11 are configured to have different thicknesses. By reducing the thickness of the first cover portion 10, the reflectivity at the first breaking 7 is increased, the reflectivity difference between different positions in the first display region 11 is reduced, and the mura phenomenon in the first display region 11 in the always-on display mode is reduced.

FIG. 11 is a cross-sectional view along line C1-C2 in FIG. 9. FIG. 12 is a schematic diagram showing a thickness of a cover layer 8 according to embodiments of the present disclosure. In some embodiments, as shown in FIG. 7 to FIG. 9 and FIG. 11 to FIG. 12, the second cover portions 9 include a second portion 14 located in the second display region 12. In the direction perpendicular to the plane of the display panel, the second portion 14 overlaps the wiring segment 5 located in the second display region 12.

The second portion 14 includes a first sub-portion 15 and a second sub-portion 16. The second sub-portion 16 and the first portion 13 have a same thickness, and the first sub-portion 15 has a thickness smaller than the thickness of the second sub-portion 16.

The metal of the first wiring layer 3 is not provided at the first breaking 7. Even the thickness of the first cover portion 10 over the first breaking 7 is reduced, the amount of the ambient lights reflected at the first breaking 7 may be less than the amount of the ambient lights reflected at other position where the metal is provided. In view of this, an embodiment of the present disclosure provides a configuration that the thickness of the first sub-portion 15 in the second display region 12 is increased, such that the thickness of the first sub-portion 15 is greater than the thickness of the second sub-portion 16. In this way, the absorbing degree or blocking degree of the first sub-portion 15 to the ambient light is increased, such that the reflectivity of the first sub-portion 15 to the ambient light is less than the reflectivity of the second sub-portion 16 to the ambient light. In this way, the reflection degree of the first sub-portion 15 to the ambient light has an analogue effect as the reflection degree of the first breaking 7 to the ambient light, such that different positions of the second display region 12 also have reflectivity difference. As a result, in the always-on display mode, the mura pattern also occurs the second display region 12, and thus the whole display region 1 has the mura pattern. Compared with the local mura pattern that only occurs in the first display region 11, the whole screen mura pattern is not easily visible to the human eye, and thus the risk that the mura pattern is observed by the human eye in the always-on display mode is further reduced.

FIG. 13 is a schematic diagram showing a layout of first sub-portions 15 and first breakings 7 according to embodiments of the present disclosure. As shown in FIG. 13, the second display region 12 includes at least one sub-regions 17. Multiple first sub-portions 15 are provided in the sub-region 17. Patterns formed by translating the first sub-portions 15 located in each sub-region 17 are in one-to-one correspondence with patterns of the first cover portions 10 that are located in the first display region 11, and overlap the patterns of the first cover portions 10 located in the first display region 11, respectively.

That is, the first sub-portions 15 in each sub-region 17 have a same layout as the first breakings 7 or the layout of the first cover portions 10 in the first display region 11. As a result, the mura patterns are periodically presented in the first display region 11 and the second display region 12. The difference between the mura pattern in the first display region 11 and the mura pattern in the second display region 12 is reduced, and thus the full screen mura is not easily visible to the human eye.

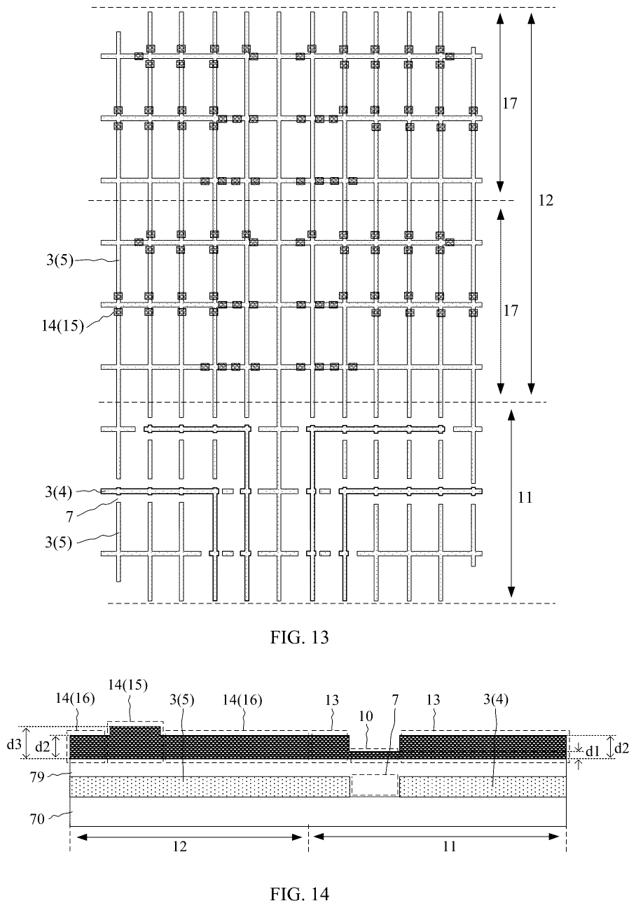

FIG. 14 is a schematic diagram showing a thickness of a cover layer 8 according to embodiments of the present disclosure. In some embodiments, the thickness d1 of the first cover portion 10, the thickness d2 of the first cover portion 13, and the thickness d3 of the first sub-portion 15 satisfy: d2−d1>d3−d2.

The thickness of the first cover portion 10 over the first breaking 7 is reduced to improve the reflectivity at the first breaking 7. Even if there is difference between the reflectivity at the first breaking 7 and the reflectivity at other position in the first display region 11, the reflectivity difference is not too large. Accordingly, the first sub-portion 15 does not need to have a too large thickness, such that the reflectivity difference between the first sub-portion 15 and the second sub-portion 16 in the second display region 12 is more similar to the reflectivity difference between the first breaking 7 and other position in the first display region 11. Therefore, the mura degree in the first display region 11 and the mura degree in the second display region 12 are more consistent.

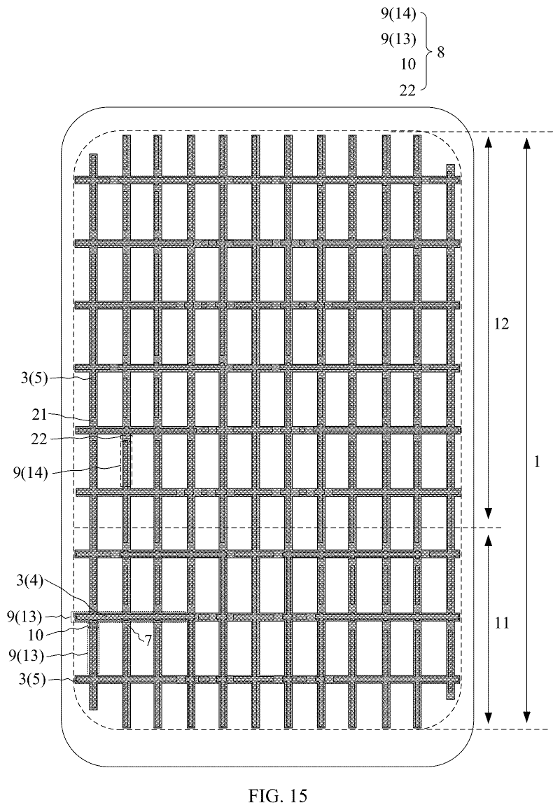

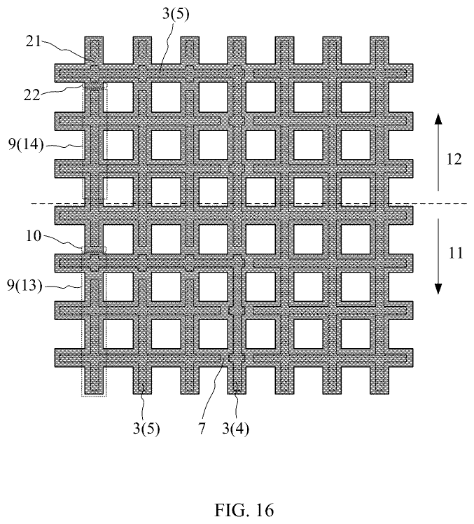

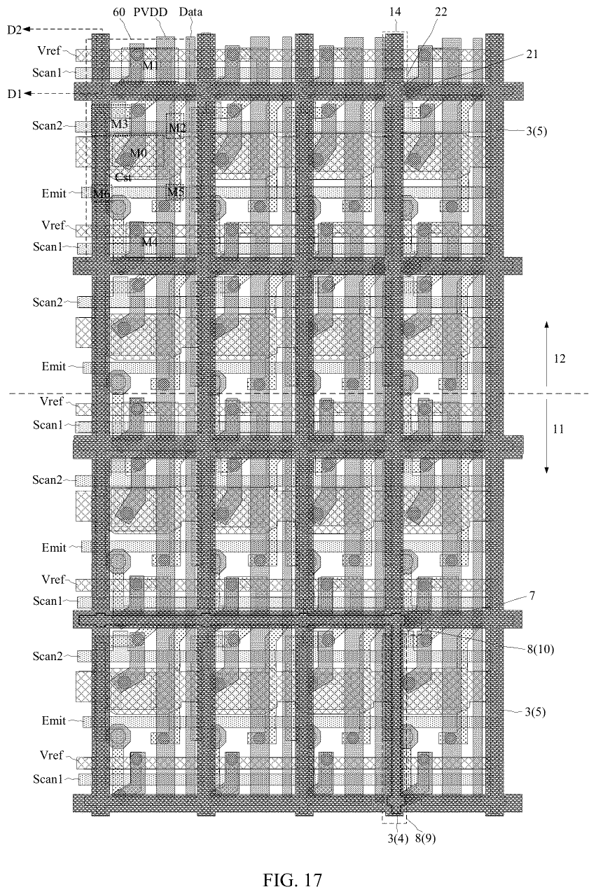

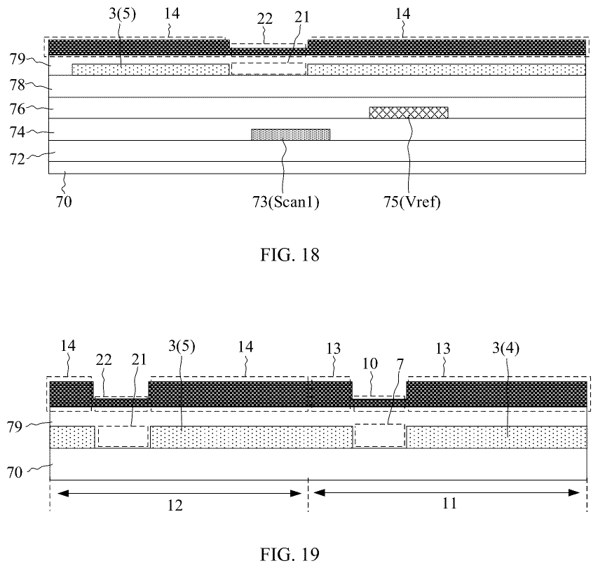

FIG. 15 is another schematic structural diagram of a display panel according to embodiments of the present disclosure. FIG. 16 is an enlarged view of a partial region of FIG. 15. FIG. 17 is a schematic diagram showing layers of a display panel according to embodiments of the present disclosure. FIG. 18 is a cross-sectional view along line D1-D2 in FIG. 17. In some embodiments, as shown in FIG. 15 to FIG. 18, each wiring segment 5 in the second display region 12 includes a second breaking 21. The cover layer 8 includes third cover portions 22 located in the second display region 12. In the direction perpendicular to the plane of the display panel, the third cover portion 22 overlaps the second breaking 21. The second cover portion 9 includes a second portion 14 located in the second display region 12. In the direction perpendicular to the plane of the display panel, the second portion 14 overlaps the wiring segment 5 located in the second display region 12. A thickness of the third cover portion 22 is smaller than a thickness of the second portion 14.

The wiring segment 5 in the second display region 12 is provided with the second breaking 21, and the thickness of the third cover portion 22 located in the cover layer 8 and corresponding to the second breaking 21 is reduced. The reflectivity condition of the stack of the third cover portion 22 and the second breaking 21 is similar to the reflectivity condition of the stack of the first cover portion 10 and the first breaking 7 in the first display region 11. In this way, the second display region 12 has a reflectivity difference at difference positions. Accordingly, the whole display region 1 has the mura pattern. Compared with the local mura pattern that only occurs in the first display region 11, the whole screen mura pattern is not easily visible to the human eye, and thus the risk that the mura pattern is observed by the human eye in the always-on display mode is further reduced.

FIG. 19 is a schematic diagram showing a thickness of a cover layer 8 according to embodiments of the present disclosure. In some embodiments, as shown in FIG. 19, the thickness of the first cover portion 10 is equal to the thickness of the third cover portion 22, and the thickness of the first portion 13 is equal to the thickness of the second portion 14. With such configuration, the difference degree of the reflectivity at different positions in the first display region 11 is substantially same as the difference degree of the reflectivity at different positions in the second display region 12, and the mura degree in the first display region 11 and the mura degree in the second display region 12 are substantially same. The whole screen mura pattern is not easily visible to the human eye.

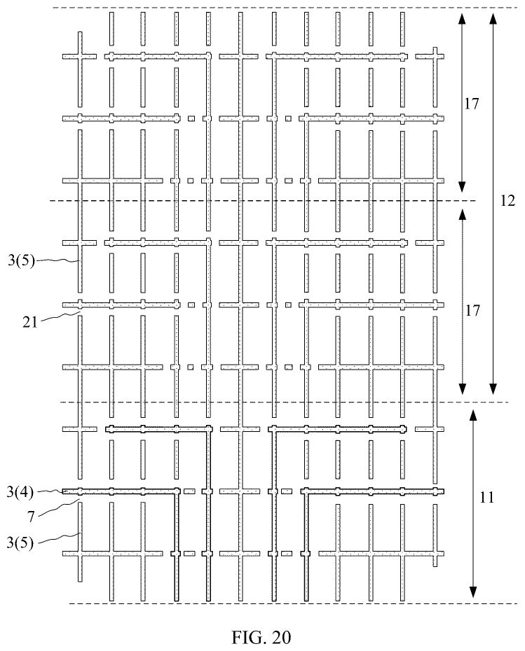

FIG. 20 is a schematic diagram showing a layout of first breakings 7 and second breakings 21 according to embodiments of the present disclosure. In some embodiments, as shown in FIG. 20, the second display region 12 includes at least one sub-region 17. Multiple second breakings 21 are provided in each sub-region 17. Patterns formed by translating the second breakings 21 located in each sub-region 17 are in one-to-one correspondence with patterns of the first breakings 7 located in the first display region 11 and overlap the patterns of the first breakings 7 located in the first display region 11, respectively. As a result, the mura patterns are periodically presented in the first display region 11 and the second display region 12. The difference between the mura pattern in the first display region 11 and the mura pattern in the second display region 12 is reduced, and thus the full screen mura is not easily visible to the human eye.

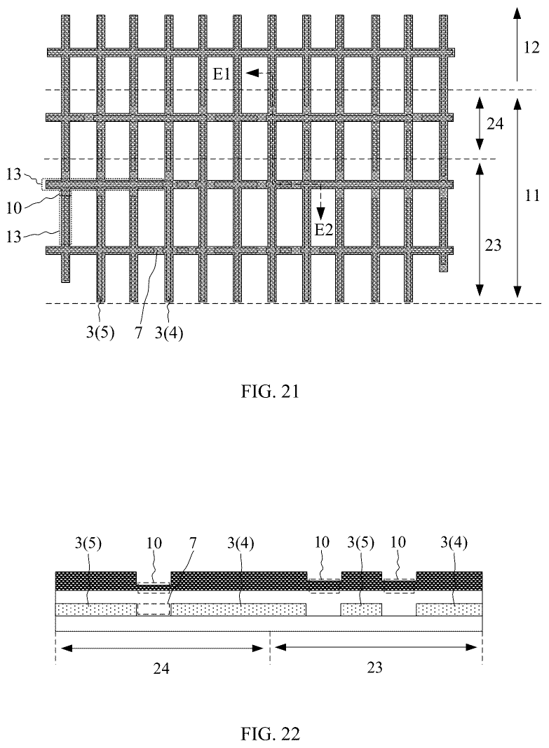

FIG. 21 is a schematic diagram showing a partial structure of a display panel according to embodiments of the present disclosure. FIG. 22 is a cross-sectional view along line E1-E2 in FIG. 21. In some embodiments, as shown in FIG. 21 and FIG. 22, the first display region 11 includes a first display sub-region 23 and a second display sub-region 24. The second display sub-region 24 is located between the first display sub-region 23 and the second display region 12. The thickness of the first cover portion 10 located in the second display sub-region 24 is smaller than the thickness of the first cover portion 10 located in the first display sub-region 23.

With such configuration, the thickness of the first cover portion 10 above the first breaking 7 in the second display sub-region 24 is smaller than the thickness of the first cover portion 10 in the first display sub-region 23. The amount of the ambient light reflected back by sidewalls of the first breaking 7 is larger, and thus the reflectivity difference between different positions in the second display sub-region 24 is reduced. In this way, the smaller the distance between the position and the second display region 12 is, the weaker the mura degree of this position is. As a result, the boundary between the area where the mura phenomenon occurs and the area where no mura phenomenon occurs is not distinct.

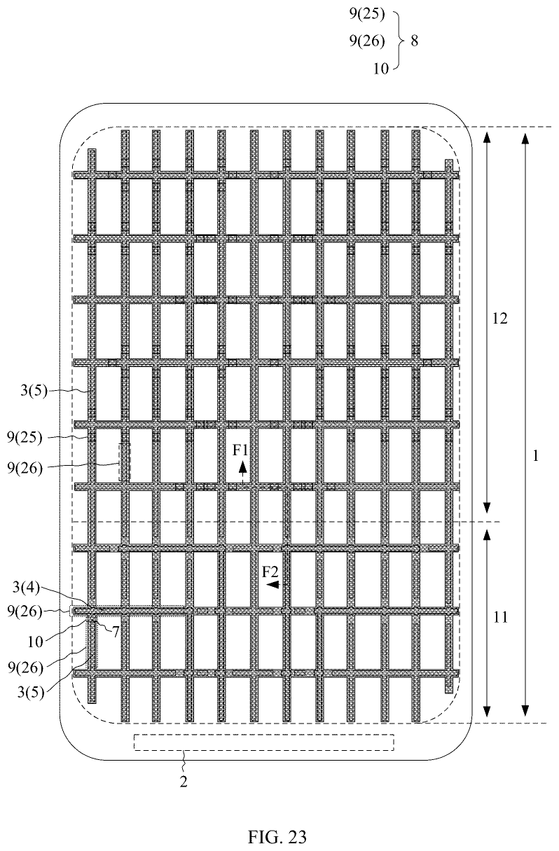

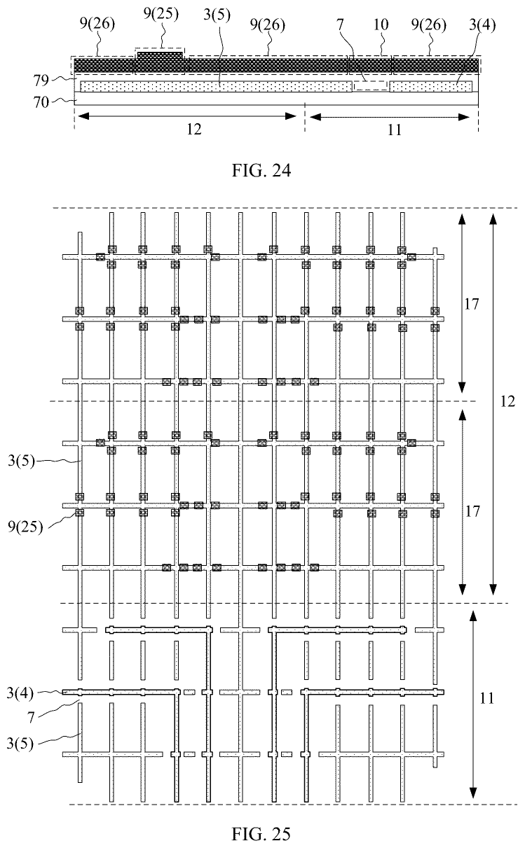

FIG. 23 is another schematic structural diagram of a display panel according to embodiments of the present disclosure. FIG. 24 is a cross-sectional view along line F1-F2 in FIG. 23. In some embodiments, as shown in FIG. 23 and FIG. 24, the display region 1 includes a first display region 11 and a second display region 12. The first display region 11 is arranged at the side of the second display region 12 close to the pad region 2. The data connection lines 4, the first breakings 7, and at least one wiring segment 5 are arranged in the first display region 11. At least another one wiring segment 5 is located in the second display region 12.

The second cover portion 9 includes a plurality of third portions 25 and a fourth portion 26. The third portions 25 are located in the second display region 12. In the direction perpendicular to the plane of the display panel, the third portions 25 overlap at least one wiring segment 5 located in the second display region 12. The fourth portions 26 are arranged in the first display region 11 and the second display region 12. In the direction perpendicular to the plane of the display panel, the fourth portions 26 in the first display region 11 overlap the data connection lines 4 and the wiring segments 5 that are located in the first display region 11, and the fourth portions 26 in the second display region 12 overlap other wiring segments 5 located in the second display region 12. The fourth portion 26 and the first cover portion 10 have a same thickness, and the thickness of the third portion 25 is greater than the thickness of the first cover portion 10.

In the above configuration, the first cover portion 10 and the second cover portion 9 in the first display region 11 have the same thickness, and the thickness of the third portion 25 in the second display region 12 is greater than this thickness. In this way, the thickness of the third portion 25 is different from the thickness of the cover portion in the second display region 12. As a result, different positions in the second display region 12 have different reflectivity due to the third portion 25, and the second display region 12 also has a mura pattern. In this way, the full display region 1 has the mura pattern. Compared with the local mura pattern that only occurs in the first display region 11, the whole screen mura pattern is not easily visible to the human eye, and thus the risk that the mura pattern is observed by the human eye in the always-on display mode is further reduced.

FIG. 25 is a schematic diagram showing a layout of third portions 25 and first breakings 7 according to embodiments of the present disclosure. In some embodiments, as shown in FIG. 25, the second display region 12 includes at least one sub-region 17. Multiple third portions 25 are provided in each sub-region 17. Patterns formed by translating the third portions 25 located in each sub-region 17 are in one-to-one correspondence with patterns of the first cover portions 10 located in the first display region 11, and overlap the patterns of the first cover portions 10 located in the first display region 11, respectively. As a result, the mura pattern is periodically presented in the first display region 11 and the second display region 12. The difference between the mura pattern in the first display region 11 and the mura pattern in the second display region 12 is reduced, and thus the full screen mura is not easily visible to the human eye.

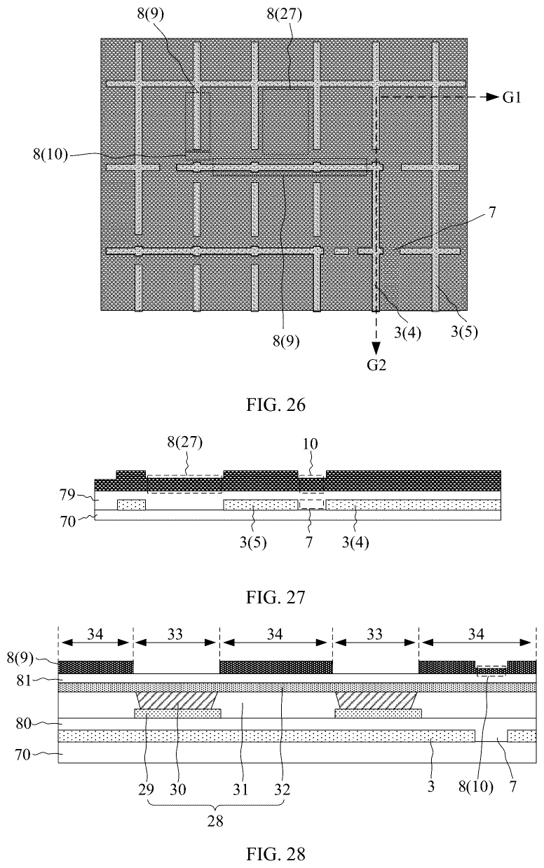

FIG. 26 is a schematic structural diagram showing another partial region of a display panel according to embodiments of the present disclosure. FIG. 27 is a cross-sectional view along line G1-G2 in FIG. 26. In some embodiments, as shown in FIG. 26 and FIG. 27, the first wiring layer 3 is a meshed layer and includes apertures. The cover layer 8 includes fourth cover portions 27. In the direction perpendicular to the plane of the display panel, the fourth cover portions 27 overlap the apertures, respectively, and the thickness of the fourth cover portion 27 is equal to the thickness of the first cover portion 10.

In some embodiments of the present disclosure, the thickness of the fourth cover portion 27 over the aperture of the first wiring layer 3 may be reduced. In this way, with the difference between the reflectivity at the first breaking 7 and the reflectivity at the data connection line 4 or the wiring segment being reduced, the difference between the reflectivity at the aperture and the reflectivity at the data connection line 4 or the wiring segment is also reduced, and the reflectivity uniformity at different positions is improved.

FIG. 28 is a cross-sectional view showing layers of a display panel according to embodiments of the present disclosure. In some embodiments, as shown in FIG. 28, the display panel further includes a light-emitting element layer 28. The light-emitting element layer 28 is located between the first wiring layer 3 and the cover layer 8. The light-emitting element layer 28 includes an anode 29, a pixel definition layer 30, a light-emitting layer 31, and a cathode 32. The pixel definition layer 30 includes openings. At least a part of the light-emitting layer 31 is located in the openings. The light-emitting element layer 28 includes light-emitting regions 33 and a non-light-emitting region 34. The light-emitting regions 33 correspond to the openings and are light-emitting positions of sub-pixels of the display panel. The first breakings 7 are located in the non-light-emitting region 34. In the direction perpendicular to the plane of the display panel, the cover layer 8 overlaps the non-light-emitting region 34, and does not overlap the light-emitting regions 33, such that the cover layer 8 does not affect the normal light-exiting of the light-emitting regions 33.

The first breakings 7 are located in the non-light-emitting region 34, such that the first breakings 7 do not affect the planarization of the anodes 29 in the light-emitting regions 33. As a result, the layer of the anodes 29 is planar, and the uniformity of lights emitted by the light-emitting layer 31 with different exiting directions is improved, avoiding color cast.

As shown in FIG. 28, the display panel may further include a second insulation layer 80 located between the first wiring layer 3 and the light-emitting element layer 28, and a third insulation layer 81 located between the light-emitting element layer 28 and the cover layer 8.

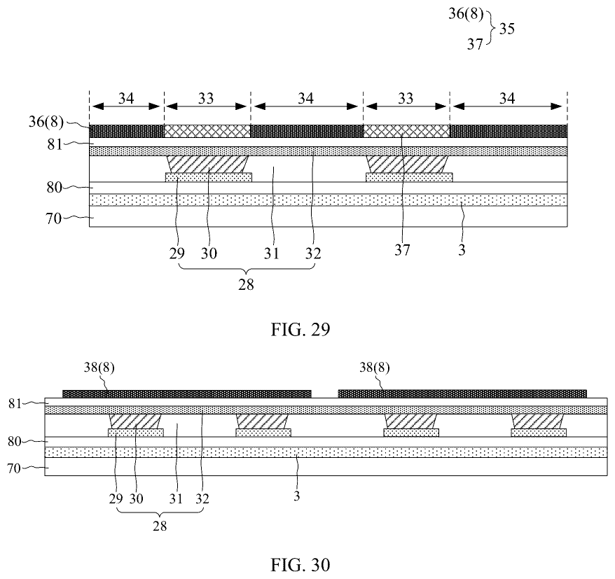

FIG. 29 is another cross-sectional view showing layers of a display panel according to embodiments of the present disclosure. In some embodiments, as shown in FIG. 29, the display panel further includes a color filter layer 35. The color filter layer 35 is located at a side of the first wiring layer 3 facing toward the light-exiting direction of the display panel. The color filter layer 35 includes a black matrix 36 and color filters 37. In some embodiments, the color filter layer 35 is located at a side of the light-emitting element layer 28 away from the first wiring layer 3. Each color filter 37 in the color filter layer 35 corresponds to a color and is used for filtering out lights of a color different from this color. The color filter layer 35 can play a light filtering role and replace a polarizer.

In some embodiments of the present disclosure, the display panel includes the color filter layer 35, and the black matrix 36 in the color filter layer 35 is reused as the cover layer 8. In one aspect, the black matrix 36 has a good light-shielding characteristic, so the black matrix 36 can reduce the reflection of the ambient light occurring at the position covered by the black matrix 36. In another aspect, it does not need to form the cover layer 8 through additional process, simplifying the process flow and reducing manufacturing cost.

FIG. 30 is another cross-sectional view showing layers of a display panel according to embodiments of the present disclosure. In some embodiments, as shown in FIG. 30, the display panel includes touch electrodes 38. The touch electrodes 38 are located at the side of the first wiring layer 3 facing toward the light-exiting direction of the display panel. In some embodiments, at least one touch electrode 38 is reused as the cover layer 8, and thus it does not need to form the cover layer 8 through additional process, simplifying the process flow and reducing manufacturing cost.

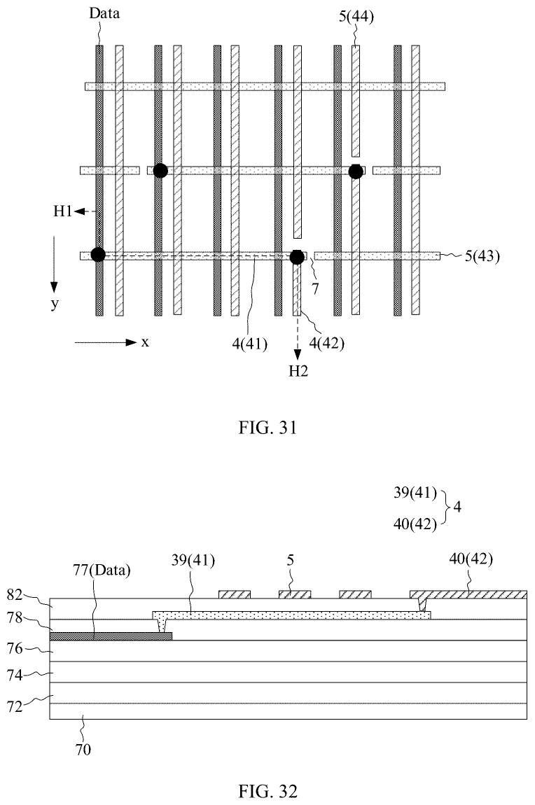

FIG. 31 is a schematic structural diagram showing another partial region of a display panel according to embodiments of the present disclosure. FIG. 32 is a cross-sectional view along line H1-H2 in FIG. 31. In some embodiments, as shown in FIG. 6, FIG. 31 and FIG. 32, the display panel further includes a first metal layer 73, a second metal layer 75, a third metal layer 77, a fourth metal layer 39 and a fifth metal layer 40. The first metal layer 73, the second metal layer 75, the third metal layer 77, the fourth metal layer 39, and the fifth metal layer 40 are sequentially stacked in the light-exiting direction of the display panel. The functions of the first metal layer 73, the second metal layer 75, and the third metal layer 77 are described in the above embodiments, and will not be repeated herein.

The data lines Data are located in the third metal layer 77. The data connection line 4 includes a part extending along a first direction x and located in the fourth metal layer 39, and a part extending along a second direction y and located in the fifth metal layer 40. The first direction x intersects the second direction y. The fourth metal layer 39 and the fifth metal layer 40 are spaced apart by a fourth insulation layer 82.

For example, the data line Data extends along the second direction y, and the data connection line 4 includes a first part 41 extending along the first direction x and a second part 42 extending along the second direction y. The first part 41 is located in the fourth metal layer 39, and the second part 42 is located in the fifth metal layer 40.

Combined with the above description regarding the first metal layer 73, the second metal layer 75 and the third metal layer 77, in the above arrangement, the data connection line 4 is formed by the fourth metal layer 39 and the fifth metal layer 40, so the routing and layout of the data connection line 4 do not affect the existing routing and layout of the display panel, thereby not affecting the process of the existing metal wires.

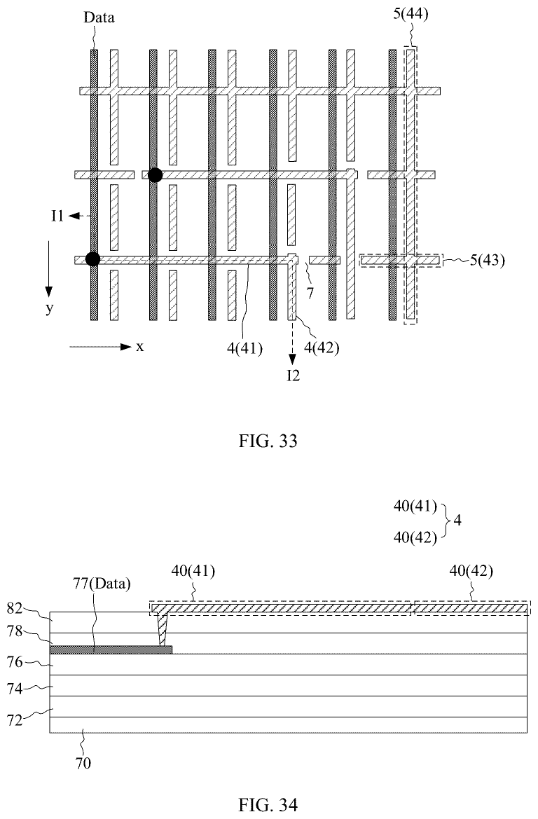

FIG. 33 is a schematic structural diagram showing another partial region of a display panel according to embodiments of the present disclosure. FIG. 34 is a cross-sectional view along line I1-I2 in FIG. 33. In some embodiments, as shown in FIG. 6, FIG. 33 and FIG. 34, the display panel further includes a first metal layer 73, a second metal layer 75, a third metal layer 77, and a fifth metal layer 40. The first metal layer 73, the second metal layer 75, the third metal layer 77, and the fifth metal layer 40 are sequentially stacked in the light-exiting direction of the display panel. The data lines Data are arranged in the third metal layer 77, and the data connection lines 4 are arranged in the fifth metal layer 40.

Combined with the above description regarding the first metal layer 73, the second metal layer 75 and the third metal layer 77, in the above arrangement, the data connection line 4 is formed by the fifth metal layer 40, so the routing and layout of the data connection line 4 do not affect the existing routing and layout of the display panel, thereby not affecting the process of the existing metal wires. In addition, the first part 41 and the second part 42 of the data connection line 4 are arranged in the same layer, and thus the reflection degree of the first part 41 to the ambient light is consistent with the reflection degree of the second part 42 to the ambient light.

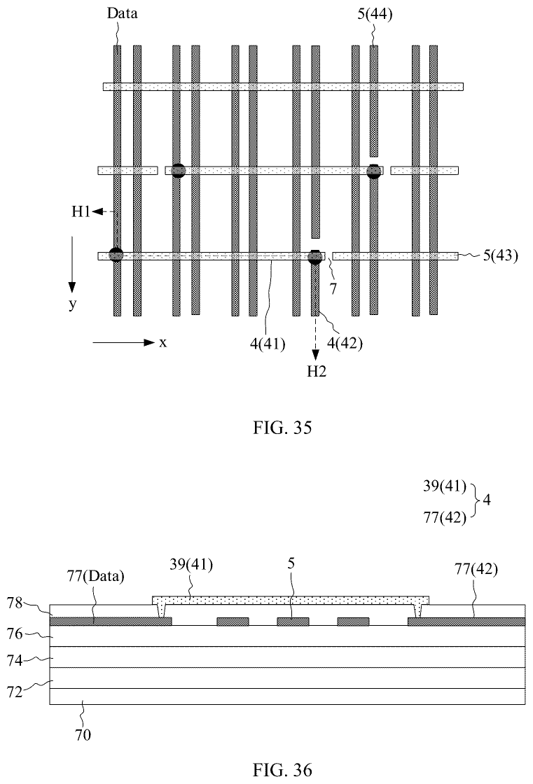

FIG. 35 is a schematic structural diagram showing another partial region of a display panel according to embodiments of the present disclosure. FIG. 36 is a cross-sectional view along line J1-J2 in FIG. 35. In some embodiments, as shown in FIG. 6, FIG. 35 and FIG. 36, the display panel further includes a first metal layer 73, a second metal layer 75, a third metal layer 77, and a fourth metal layer 39. The first metal layer 73, the second metal layer 75, the third metal layer 77, and the fourth metal layer 39 are sequentially stacked in the light-exiting direction of the display panel. The data lines Data are arranged in the third metal layer 77. The data connection line 4 includes a first part extending in a same direction as the data line Data, and a second part extending in a direction intersecting the extending direction of the data line Data. The first part of the data connection line 4 is located in the third metal layer 77, and the second part of the data connection line 4 is located in the fourth metal layer 39.

In the above arrangement, although the data connection line 4 is arranged in two layers, the part of the data connection line 4 located in the same layer as the data line Data may be formed by the same patterning process as the data line Data, simplifying the process flow. The part of the data connection line 4 located in the same layer as the data line Data extends in the same direction as the data line Data, avoiding the short-circuiting therebetween.

In some embodiments, as shown in FIG. 31, FIG. 33 and FIG. 35, the data connection line 4 includes a first part 41 extending along the first direction x and a second part 42 extending along the second direction y. The wiring segments 5 include first-type wiring segments 43 extending along the first direction x and second-type wiring segments 44 extending along the second direction y intersecting the first direction x. The first-type wiring segments 43 are arranged in the same layer as the first part 41, and a first-type wiring segment 43 of the first-type wiring segments 43 is aligned with the first part 41 along the first direction x. The second-type wiring segments 44 are arranged in the same layer as the second part 42, and a second-type wiring segment 44 of the second-type wiring segments 44 is aligned with the second part 42 along the second direction y. With such arrangement, the data connection lines 4 and the wiring segments 5 are arranged more regularly, and the data connection lines 4 and the wiring segments 5 can be formed simultaneously, such that the wiring segments 5 do not need additional forming process and occupy an additional layer.

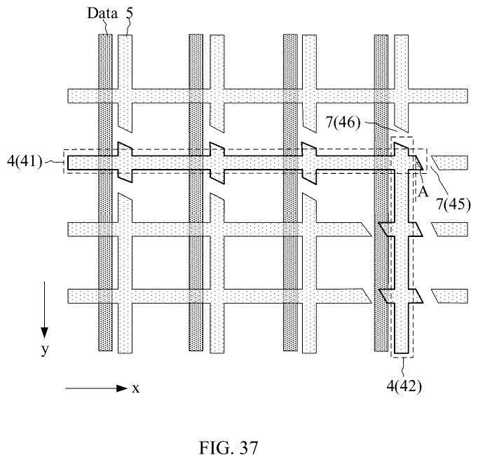

FIG. 37 is a schematic structural diagram of a first breaking 7 according to embodiments of the present disclosure. In some embodiments, as shown in FIG. 37, in the direction perpendicular to the plane of the display panel (in the plan view), an included angle A between an extending direction of at least one edge of the first breaking 7 and an extending direction of the data line Data, satisfies 0°<A<90°.

With such configuration, the edge of the first breaking 7 is inclined with respect to the first direction x. For example, the included angle A is equal to 45°. In this way, the transmission angle of the light reflected by the sidewall of the data connection line 4 or the wiring segment 5 at the first breaking 7 is different when viewed from different viewing angles, and thus the visibility of the first breaking 7 is reduced.

In some embodiments, as shown in FIG. 37, the data connection line 4 includes a first part 41 extending along the first direction x and a second part 42 extending along the second direction y. The first breakings 7 include a first-A breaking 45 located between the first part 41 and the wiring segment 5, and a first-B breaking 46 between the second part 42 and another wiring segment 5. In the direction perpendicular to the plane of the display panel, at least one edge of the first-A breaking 45 and at least one edge of the first-B breaking 46 are different in extending direction. In this way, when the display panel is viewed from a same viewing angle, the ambient lights that are reflected by edges of different first breakings 7 and received by the human eyes are different in amount, and thus the visibility of the first breaking 7 is further reduced.

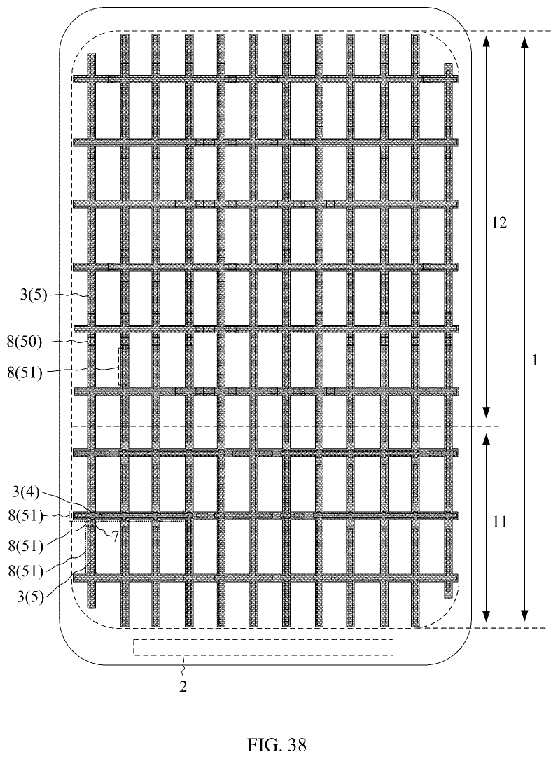

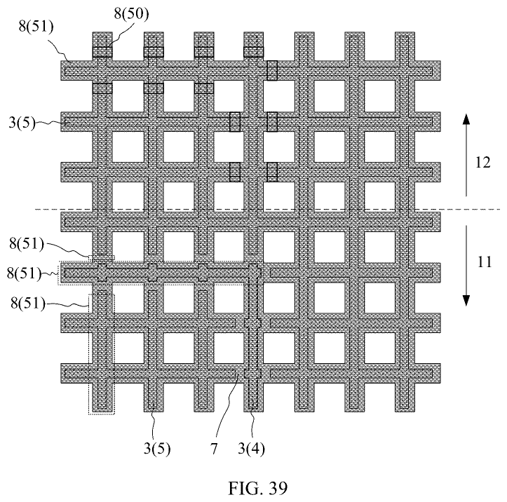

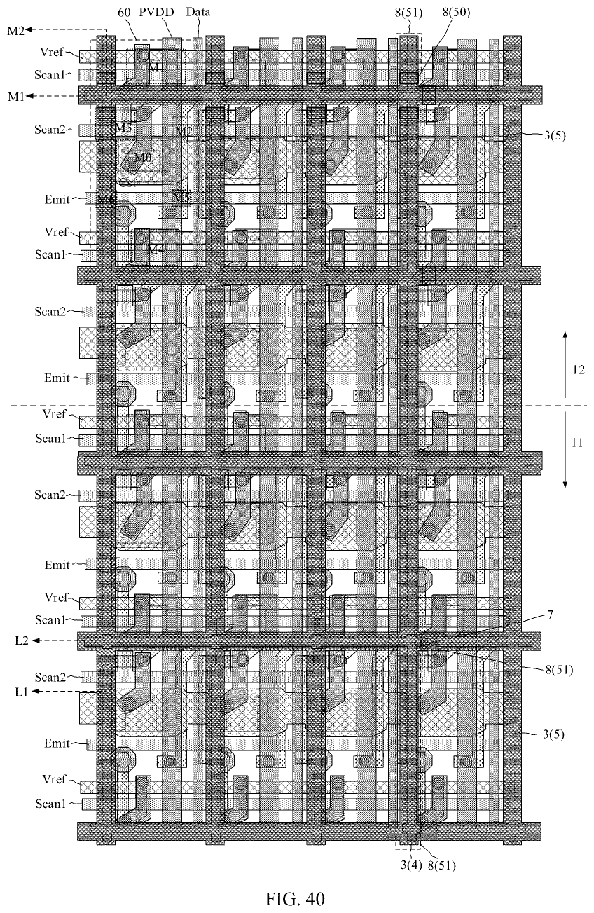

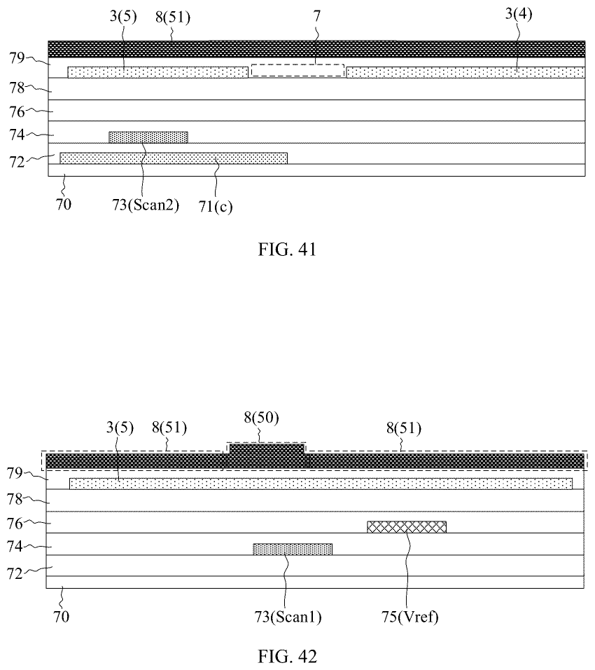

FIG. 38 is another schematic structural diagram of a display panel according to embodiments of the present disclosure. FIG. 39 is an enlarged view of a partial region of FIG. 38. FIG. 40 is another schematic diagram showing layers of a display panel according to embodiments of the present disclosure. FIG. 41 is a cross-sectional view along line L1-L2 in FIG. 40. FIG. 42 is a cross-sectional view along line M1-M2 in FIG. 40. In some embodiments, as shown in FIG. 38 to FIG. 42, the display panel includes a display region 1 and a pad region 2. The display region 1 includes a first display region 11 and a second display region 12. The first display region 11 is located at a side of the second display region 12 close to the pad region 2.

The display panel includes data lines Data arranged in the display region 1 and a first wiring layer 3 arranged in the display region 1. The first wiring layer 3 includes data connection lines 4 and wiring segments 5. The data connection lines 4 are located in the first display region 11. At least two data connection lines 4 are connected to at least two data lines Data, and each are configured to transmit a data voltage provided in the pad region 2 to a corresponding one of the at least two data line Data. The wiring segments 5 are located in the first display region 11 and the second display region 12. At least one wiring segment 5 is spaced apart from the data connection line 4 by a first breaking 7.

The display panel further includes a cover layer 8. The cover layer 8 is located at the side of the first wiring layer 3 facing toward the light-exiting direction of the display panel. The cover layer 8 includes fifth cover portions 50 and sixth cover portions 51. The fifth cover portion 50 is arranged in the second display region 12. In the direction perpendicular to the plane of the display panel, the fifth cover portion 50 overlaps the wiring segment 5 located in the second display region 12. The sixth cover portions 51 are arranged in the first display region 11 and the second display region 12. In the direction perpendicular to the plane of the display panel, the sixth cover portion 51 in the first display region 11 covers the first breaking 7, the data connection line 4, and the wiring segment 5 that are located in the first display region 11, and the sixth cover portions 51 in the second display region 11 overlap other wiring segments 5 located in the second display region 12. The thickness of the fifth cover portion 50 is greater than the thickness of the sixth cover portion 51.

In some embodiments of the present disclosure, the cover layer 8 is arranged above the first wiring layer 3, and the cover layer 8 have different thicknesses at different positions. The different thicknesses of the cover layer 8 can reduce the risk that the mura phenomenon caused by the first breaking 7 is observed by the human eye. Specifically, in some embodiments of the present disclosure, the thickness of the fifth cover portion 50 in the second display region 12 is increased, and the difference between the thickness of the sixth cover portion 51 and the thickness of the fifth cover portion 50 in the second display region 12 can cause reflectivity difference at different positions, such that the mura pattern also occurs in the second display region 12. Accordingly, the whole display region 1 has the mura pattern. Compared with the local mura pattern that only occurs in the first display region 11, the whole screen mura pattern is not easily visible to the human eye, and thus the risk that the mura pattern is observed by the human eye in the always-on display mode is further reduced.

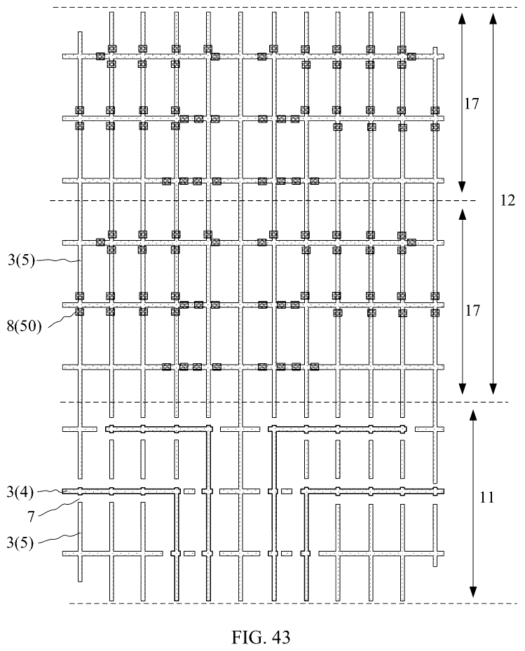

FIG. 43 is a schematic diagram showing a layout of fifth cover portions 50 and first breakings 7 according to embodiments of the present disclosure. In some embodiments, as shown in FIG. 43, the second display region 12 includes at least one sub-region 17. Multiple fifth cover portions 50 are arranged in the sub-region 17. Patterns formed by translating the fifth cover portions 50 are in one-to-one correspondence with patterns of the first breakings 7 located in the first display region 11, and overlap the patterns of the first breakings 7, respectively. As a result, the mura patterns are periodically presented in the first display region 11 and the second display region 12. The difference between the mura pattern in the first display region 11 and the mura pattern in the second display region 12 is reduced, and thus the full screen mura is not easily visible to the human eye.

In some embodiments, as shown in FIG. 28, the display panel further includes a light-emitting element layer 28. The light-emitting element layer 28 is located between the first wiring layer 3 and the cover layer 8. The light-emitting element layer 28 includes light-emitting regions 33 and a non-light-emitting region 34. The light-emitting element layer 28 includes an anode 29, a pixel definition layer 30, a light-emitting layer 31, and a cathode 32. The pixel definition layer 30 includes openings. At least a part of the light-emitting layer 31 is located in the openings. The light-emitting element layer 28 includes light-emitting regions 33 and a non-light-emitting region 34. The light-emitting regions 33 correspond to the openings and are light-emitting positions of sub-pixels of the display panel. The first breakings 7 are located in the non-light-emitting region 34. In the direction perpendicular to the plane of the display panel, the cover layer 8 overlaps the non-light-emitting region 34, and does not overlap the light-emitting regions 33, such that the cover layer 8 does not affect the normal light-exiting of the light-emitting regions 33.

The first breakings 7 are located in the non-light-emitting region 34, such that the first breakings 7 do not affect the planarization of the anodes 29 in the light-emitting regions 33. As a result, the layer of the anodes 29 is planar, and the uniformity of lights emitted by the light-emitting layer 31 with different exiting directions is improved, avoiding color cast.

In some embodiments, as shown in FIG. 29, the display panel further includes a color filter layer 35. The color filter layer 35 is located at a side of the first wiring layer 3 facing toward the light-exiting direction of the display panel. The color filter layer 35 includes a black matrix 36 and color filters 37. In some embodiments, the color filter layer 35 is located at a side of the light-emitting element layer 28 away from the first wiring layer 3. Each color filter 37 in the color filter layer 35 corresponds to a color and is used for filtering out lights of a color different from this color. The color filter layer 35 can play a light filtering role and replace a polarizer.

In some embodiments of the present disclosure, the display panel includes the color filter layer 35, and the black matrix 36 in the color filter layer 35 is reused as the cover layer 8. In one aspect, the black matrix 36 has a good light-shielding characteristic, so the black matrix 36 can reduce the reflection of the ambient light occurring at the position covered by the black matrix 36. In another aspect, it does not need to form the cover layer 8 through additional process, simplifying the process flow and reducing manufacturing cost.

In some embodiments, as shown in FIG. 30, the display panel further includes touch electrodes 38. The touch electrodes 38 are located at the side of the first wiring layer 3 facing toward the light-exiting direction of the display panel. In some embodiments, at least one touch electrode 38 is reused as the cover layer 8, and thus it does not need to form the cover layer 8 through additional process, simplifying the process flow and reducing manufacturing cost.

In some embodiments, as shown in FIG. 6, FIG. 31 and FIG. 32, the display panel further includes a first metal layer 73, a second metal layer 75, a third metal layer 77, a fourth metal layer 39 and a fifth metal layer 40. The first metal layer 73, the second metal layer 75, the third metal layer 77, the fourth metal layer 39 and the fifth metal layer 40 are sequentially stacked in the light-exiting direction of the display panel. The data lines Data are located in the third metal layer 77. The data connection line 4 includes a part extending along a first direction x and located in the fourth metal layer 39, and a part extending along a second direction y and located in the fifth metal layer 40. The first direction x intersects the second direction y.

For example, the data line Data extends along the second direction y, and the data connection line 4 includes a first part 41 extending along the first direction x and a second part 42 extending along the second direction y. The first part 41 is located in the fourth metal layer 39, and the second part 42 is located in the fifth metal layer 40.

Combined with the above description regarding the first metal layer 73, the second metal layer 75 and the third metal layer 77, in the above arrangement, the data connection line 4 is formed by the fourth metal layer 39 and the fifth metal layer 40, so the routing and layout of the data connection line 4 do not affect the existing routing and layout of the display panel, thereby not affecting the process of the existing metal wires.

In some embodiments, as shown in FIG. 6, FIG. 33 and FIG. 34, the display panel further includes a first metal layer 73, a second metal layer 75, a third metal layer 77, and a fifth metal layer 40. The first metal layer 73, the second metal layer 75, the third metal layer 77, and the fifth metal layer 40 are sequentially stacked in the light-exiting direction of the display panel. The data lines Data are arranged in the third metal layer 77, and the data connection lines 4 are arranged in the fifth metal layer 40.

Combined with the above description regarding the first metal layer 73, the second metal layer 75 and the third metal layer 77, in the above arrangement, the data connection line 4 is formed by the fifth metal layer 40, so the routing and layout of the data connection line 4 do not affect the existing routing and layout of the display panel, thereby not affecting the process of the existing metal wires. In addition, the first part 41 and the second part 42 of the data connection line 4 are arranged in the same layer, and thus the reflection degree of the first part 41 to the ambient light is consistent with the reflection degree of the second part 42 to the ambient light.

In some embodiments, as shown in FIG. 6, FIG. 35 and FIG. 36, the display panel further includes a first metal layer 73, a second metal layer 75, a third metal layer 77, and a fourth metal layer 39. The first metal layer 73, the second metal layer 75, the third metal layer 77, and the fourth metal layer 39 are sequentially stacked in the light-exiting direction of the display panel. The data lines Data are arranged in the third metal layer 77. The data connection line 4 includes a first part extending in a same direction as the data line Data, and a second part extending in a direction intersecting the extending direction of the data line Data. The first part of the data connection line 4 is located in the third metal layer 77, and the second part of the data connection line 4 is located in the fourth metal layer 39.

In the above arrangement, although the data connection line 4 is arranged in two layers, the part of the data connection line 4 located in the same layer as the data line Data may be formed by the same patterning process as the data line Data, simplifying the process flow. The part of the data connection line 4 located in the same layer as the data line Data extends in the same direction as the data line Data, avoiding the short-circuiting therebetween.

In some embodiments, as shown in FIG. 31, FIG. 33 and FIG. 35, the data connection line 4 includes a first part 41 extending along the first direction x and a second part 42 extending along the second direction y. The wiring segments 5 include first-type wiring segments 43 extending along the first direction x and second-type wiring segments 44 extending along the second direction y intersecting the first direction x. The first-type wiring segments 43 are arranged in the same layer as the first part 41, and a first-type wiring segment 43 of the first-type wiring segments 43 is aligned with the first part 41 along the first direction x. The second-type wiring segments 44 are arranged in the same layer as the second part 42, and a second-type wiring segment 44 of the second-type wiring segments 44 is aligned with the second part 42 along the second direction y. With such arrangement, the data connection lines 4 and the wiring segments 5 are arranged more regularly, and the data connection lines 4 and the wiring segments 5 can be formed simultaneously, such that the wiring segments 5 do not need additional forming process and occupy an additional layer.

In some embodiments, as shown in FIG. 37, in the direction perpendicular to the plane of the display panel (in the plan view), an included angle A between an extending direction of at least one edge of the first breaking 7 and the extending direction of the data line Data satisfies 0°<A<90°.

With such configuration, the edge of the first breaking 7 is inclined with respect to the first direction x. For example, the included angle A is equal to 45°. In this way, the transmission direction/angle of the light reflected by the sidewall of the data connection line 4 or the wiring segment 5 at the first breaking 7 is different when viewed from different viewing directions/angles, and thus the visibility of the first breaking 7 is further reduced.

In some embodiments, as shown in FIG. 37, the data connection line 4 includes a first part 41 extending along the first direction x and a second part 42 extending along the second direction y. The first breakings 7 include a first-A breaking 45 located between the first part 41 and the wiring segment 5, and a first-B breaking 46 between the second part 42 and another wiring segment 5. In the direction perpendicular to the plane of the display panel, at least one edge of the first-A breaking 45 and at least one edge of the first-B breaking 46 are different in extending direction. In this way, when the display panel is viewed from a same viewing angle, the ambient lights that are reflected by edges of different first breakings 7 and received by the human eyes are different in amount, and thus the visibility of the first breaking 7 is further reduced.

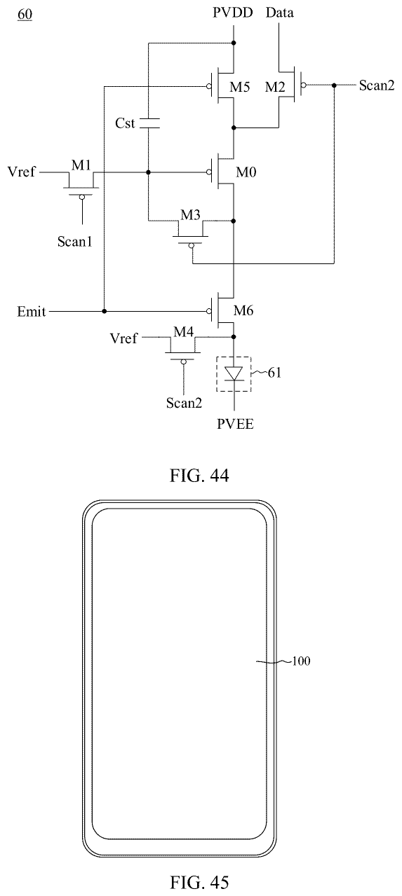

The display panel described above may include a pixel circuit. FIG. 44 is a schematic diagram of a pixel circuit 60 according to embodiments of the present disclosure. In some embodiments, as shown in FIG. 5 and FIG. 44, the pixel circuit 60 includes: a driving transistor M0, a gate reset transistor M1, a data input transistor M2, a threshold compensation transistor M3, an anode reset transistor M4, a first emission control transistor M5, a second emission control transistor M6, and a storage capacitor Cst.

The gate reset transistor M1 includes: a gate electrically connected to a first scan signal line Scan1, a first electrode electrically connected to a reset signal line Vref, and a second electrode electrically connected to a gate of the driving transistor M0. The gate reset transistor M1 is configured to reset the potential of the gate of the driving transistor M0 when the gate reset transistor M1 is turned on.

The anode reset transistor M4 includes: a gate electrically connected to a second scan signal line Scan2, a first electrode electrically connected to the reset signal line Vref, and a second electrode electrically connected to an anode of a light-emitting element 61. The anode reset transistor M4 is configured to reset the potential of the anode of the light-emitting element 61 when the anode reset transistor M4 is turned on.

A gate of the data input transistor M2 and a gate of the threshold compensation transistor M3 are both connected to the second scan signal line Scan2. A first electrode of the data input transistor M2 is electrically connected to the data line Data, and a second electrode of the data input transistor M2 is electrically connected to a first electrode of the driving transistor M0. A first electrode of the threshold compensation transistor M3 is electrically connected to a second electrode of the driving transistor M0, and a second electrode of the threshold compensation transistor M3 is electrically connected to the gate of the driving transistor M0. The data input transistor M2 and the threshold compensation transistor M3 are configured to charge the gate of the driving transistor M0 and compensate the threshold voltage of the driving transistor M0, when the data input transistor M2 and the threshold compensation transistor M3 are turned on.

A gate of the first emission control transistor M5 and a gate of the second emission control transistor M6 are both electrically connected to an emission control signal line Emit. A first electrode of the first emission control transistor M5 is electrically connected to a power supply signal line PVDD, and a second electrode of the first emission control transistor M5 is electrically connected to the first electrode of the driving transistor M0. A first electrode of the second emission control transistor M6 is electrically connected to the second electrode of the driving transistor M0, and a second electrode of the second emission control transistor M6 is electrically connected to the anode of the light-emitting element 61. When the first emission control transistor M5 and the second emission control transistor M6 are turned on, the first emission control transistor M5 and the second emission control transistor M6 are configured to transmit the driving current generated by the driving transistor M0 to the light-emitting element 61 so as drive the light-emitting element 61 to emit light.

For two adjacent rows of pixel circuits 60, the second scan signal line corresponding to the previous row of pixel circuits 60 may be reused as the first scan signal line corresponding to the latter row of pixel circuits 60. As shown in FIG. 5, the first scan signal line electrically connected to the anode reset transistor M4 can be regarded as the second scan signal line of the present row of pixel circuits 60, and can also be regarded as the first scan signal line of the next row of pixel circuits 60.

An embodiment of the present disclosure provides a display device. FIG. 45 is a schematic structural diagram of a display device according to embodiments of the present disclosure. As shown in FIG. 45, the display device includes a display panel 100. The display panel 100 of the display device may be configured according to the structure shown in FIG. 3 to FIG. 37 or be configured according to the structure shown in FIG. 38 to FIG. 43. The two panel structures of the display panel 100 have been described in the above embodiments and will not be repeated herein. The display device shown in FIG. 45 is for illustration. The display device may be any device having a display function, such as a mobile phone, a tablet, a notebook computer, an e-book, or a television.

The above illustrates only some embodiments of the present disclosure and are not intended to limit the present disclosure. Any modifications, equivalent replacements, improvements, and the like made within the principle of the present disclosure are intended to be included within the protection scope of the present disclosure.

Finally, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, having a display region and a pad region, and comprising:
a plurality of data lines arranged in the display region;
a first wiring layer arranged in the display region and comprising a plurality of data connection lines and a plurality of wiring segments, wherein one data connection line of the plurality of data connection lines is connected to at least one data line of the plurality of data lines and is configured to transmit a data voltage provided in the pad region to the at least one data line, and one wiring segment of the plurality of wiring segments is spaced apart from one data connection line of the plurality of data connection lines by one first breaking of first breakings; and
a cover layer arranged at a side of the first wiring layer facing toward a light-exiting direction of the display panel and comprising first cover portions and second cover portions, wherein along a direction perpendicular to a plane of the display panel, the first cover portions overlap the first breakings, respectively, and the second portions overlap the plurality of data connection lines and the plurality of wiring segments,
wherein one of the first cover portions has a thickness smaller than a thickness of one of the second cover portions.

2. The display panel according to claim 1, wherein the display region comprises a first display region and a second display region, wherein the first display region is located at a side of the second display region close to the pad region; the plurality of data connection lines, the first breakings, and at least one wiring segment of the plurality of wiring segments are arranged in the first display region; and at least another one wiring segment of the plurality of wiring segments is arranged in the second display region;
wherein the second cover portions comprise a first portion arranged in the first display region, wherein along the direction perpendicular to the plane of the display panel, the first portion overlaps one of the plurality of data connection lines arranged in the first display region, and overlaps one the at least one wiring segment arranged in the first display region; and
wherein the thickness of the one of the first cover portions is smaller than a thickness of the first portion.

3. The display panel according to claim 2, wherein the second cover portions further comprise at least one second portion arranged in the second display region, wherein along the direction perpendicular to the plane of the display panel, one of the at least one second portion overlaps one of the at least another one wiring segment arranged in the second display region; and
wherein one of the at least one second portion comprises a first sub-portion and a second sub-portion, wherein the second sub-portion and the first portion have a same thickness, and the first sub-portion has a thickness greater than a thickness of the second sub-portion.

4. The display panel according to claim 3, wherein the second display region comprises at least one sub-region, and the at least one second portion comprises a plurality of second portions, wherein at least two first sub-portion of a plurality of first sub-portions of the plurality of second portions are provided in each of the at least one sub-region, and patterns form by translating the at least two first sub-portions in each of the at least one sub-region are in one-to-one correspondence with patterns of at least two first cover portions of the first cover portions located in the first display region, and overlap the patterns of the at least two first cover portions, respectively.

5. The display panel according to claim 3, wherein the thickness of one of the first cover portions is d1, the thickness of the first portion is d2, and the thickness of one of the at least one first sub-portion is d3, where d2−d1>d3−d2.

6. The display panel according to claim 2, wherein one of the at least another one wiring segment arranged in the second display region has at least one second breaking,
wherein the cover layer further comprises at least one third cover portion arranged in the second display region, wherein one of the at least one third cover portion overlaps one of the at least one second breaking along the direction perpendicular to the plane of the display panel, and
wherein the second cover portions further comprise a second portion arranged in the second display region, wherein along the direction perpendicular to the plane of the display panel, the second portion overlaps one of the at least another one wiring segment arranged in the second display region, and one of the at least one third cover portion each has a thickness smaller than a thickness of the second portion.

7. The display panel according to claim 6, wherein at least one first cover portion of the first cover portions and the at least one third cover portion have a same thickness, and the first portion and the at least one second portion have a same thickness.

8. The display panel according to claim 6, wherein the second display region comprises at least one sub-region, the at least another one wiring segment arranged in the second display region comprises at least another two wiring segments, the at least another two wiring segments arranged in the second display region have the second breakings, and at least two second breakings of the second breakings are provided in each of the at least one sub-region, and patterns formed by translating the at least two second breakings in each of the at least one sub-region are in one-to-one correspondence with the first breakings located in the first display region, and overlap the plurality of first breakings, respectively.

9. The display panel according to claim 2, wherein the first display region comprises a first display sub-region and a second display sub-region, wherein the second display sub-region is located between the first display sub-region and the second display region; and
wherein one first cover portion of the first cover portions that is located in the second display sub-region has a thickness smaller than a thickness of another first cover portion of the first cover portions that is located in the first display sub-region.

10. The display panel according to claim 1, wherein the display region comprises a first display region and a second display region, wherein the first display region is located at a side of the second display region close to the pad region; the plurality of data connection lines, the first breakings, and at least one wiring segment of the plurality of wiring segments are arranged in the first display region; and at least another one wiring segment of the plurality of wiring segments is arranged in the second display region;
wherein the second cover portions comprise at least one third portion and a fourth portion, wherein the at least one third portion is arranged in the second display region; and along the direction perpendicular to the plane of the display panel, one of the at least one third portion overlaps one of the at least another one wiring segment located in the second display region; the fourth portion is arranged in the first display region and the second display region; and along the direction perpendicular to the plane of the display panel, the fourth portion overlaps one of the plurality of data connection lines that is located in the first display region and overlaps one of the at least one wiring segment that is located in the first display region, and the fourth portion overlaps the at least another one wiring segment located in the second display region, and
wherein the fourth portion and at least one first cover portion of the first cover portions have a same thickness, and one of the at least one third portion has a thickness greater than the thickness of the one of the first cover portions.

11. The display panel according to claim 10, wherein the second display region comprises at least one sub-region, and the at least one third portion comprises a plurality of third portions, wherein at least two third portions are provided in each of the at least one sub-region, and patterns formed by translating the at least two third portions in each of the at least one sub-region are in one-to-one correspondence with patterns of the first cover portions located in the first display region and overlap the patterns of the first cover portions, respectively.

12. The display panel according to claim 1, wherein the first wiring layer is a meshed layer and comprises a plurality of apertures, and
wherein the cover layer further comprises a plurality of fourth cover portions respectively overlapping the plurality of apertures along the direction perpendicular to the plane of the display panel, wherein one fourth cover portion of the plurality of fourth cover portions and one first cover portion of the first cover portions have a same thickness.

13. The display panel according to claim 1, further comprising:
a light-emitting element layer arranged between the first wiring layer and the cover layer and comprising a light-emitting region and a non-light-emitting region,
wherein one of the first breakings is arranged in the light-emitting region; and along the direction perpendicular to the plane of the display panel, the cover layer overlaps the non-light-emitting region and does not overlap the light-emitting region.

14. The display panel according to claim 1, further comprising:
a color filter layer arranged at a side of the first wiring layer facing toward the light-exiting direction of the display panel, wherein the color filter layer comprises a black matrix and a color filter, wherein the black matrix is reused as the cover layer.

15. The display panel according to claim 1, further comprising:
a plurality of touch electrodes arranged at a side of the first wiring layer facing toward the light-exiting direction of the display panel, wherein at least one of the plurality of touch electrodes is reused as the cover layer.

16. The display panel according to claim 1, further comprising:
a first metal layer, a second metal layer, a third metal layer, a fourth metal layer, and a fifth metal layer that are sequentially stacked along the light-exiting direction of the display panel,
wherein the plurality of data lines are arranged in the third metal layer, and one of the plurality of data connection lines comprises a part extending along a first direction and arranged in the fourth metal layer, and another part extending along a second direction and arranged in the fifth metal layer, the first direction intersecting the second direction.

17. The display panel according to claim 1, further comprising:
a first metal layer, a second metal layer, a third metal layer, and a fifth metal layer that are sequentially stacked along the light-exiting direction of the display panel,
wherein the plurality of data lines are arranged in the third metal layer, and the plurality of data connection lines are arranged in the fifth metal layer.

18. The display panel according to claim 1, further comprising:
a first metal layer, a second metal layer, a third metal layer, and a fourth metal layer that are sequentially stacked along the light-exiting direction of the display panel,
wherein the plurality of data lines are arranged in the third metal layer, and each of the plurality of data connection lines comprises a first part extending along a same direction as the plurality of data lines and arranged in the third metal layer, and a second part extending along a direction intersecting an extending direction of the plurality of data lines and arranged in the fourth metal layer.

19. The display panel according to claim 1, wherein one of the plurality of data connection lines comprises a first part extending along a first direction and a second part extending along a second direction intersecting the first direction, and the plurality of wiring segments comprise at least one first-type wiring segment each extending along the first direction and at least one second-type wiring segment each extending along the second direction; and
wherein the at least one first-type wiring segment is arranged in a same layer as the first part, and one of the at least one first-type wiring segment is aligned with the first part along the first direction; and the at least one second-type wiring segment is arranged in a same layer as the second part, and one of the at least one second-type wiring segment is aligned with the second part along the second direction.

20. The display panel according to claim 1, wherein along the direction perpendicular to the plane of the display panel, one of the first breakings has at least one edge, and an included angle A formed between an extending direction of one of the at least one edge and an extending direction of one of the plurality of data lines satisfy: 0°<A<90°.

21. The display panel according to claim 1, wherein one of the plurality of data connection lines comprises a first part extending along a first direction and a second part extending along a second direction intersecting the first direction, the first breakings comprise a first-A breaking located between the first part and one of the plurality of wiring segments and a first-B breaking located between the second part and one of the plurality of wiring segments, and
wherein along the direction perpendicular to the plane of the display panel, at least one edge of the first-A breaking and at least one edge of the first-B breaking extend along different directions.

22. A display device, comprising:
a display panel,
wherein the display panel has a display region and a pad region, and comprises:
a plurality of data lines arranged in the display region;
a first wiring layer arranged in the display region and comprising a plurality of data connection lines and a plurality of wiring segments, wherein one data connection line of the plurality of data connection lines is connected to at least one data line of the plurality of data lines and is configured to transmit a data voltage provided in the pad region to the at least one data line, and one wiring segment of the plurality of wiring segments is spaced apart from one data connection line of the plurality of data connection lines by one first breaking of first breakings; and
a cover layer arranged at a side of the first wiring layer facing toward a light-exiting direction of the display panel and comprising first cover portions and second cover portions, wherein along a direction perpendicular to a plane of the display panel, the first cover portions overlap the first breakings, respectively, and the second portions overlap the plurality of data connection lines and the plurality of wiring segments, wherein one of the first cover portions has a thickness smaller than a thickness of one of the second cover portions.
